(19) United States
(12) Patent Application Publication
(10) Pub. No.: US 2005/0196946 A1
(43) Pub. Date: Sep. 8, 2005

(54) Method for manufacturing solid-state imaging device

(75) Inventor: Ken Henmi, Takatsuki-shi (JP)

Correspondence Address: MERCHANT & GOULD PC, P.O. BOX 2903, MINNEAPOLIS, MN, 55402-0903, US

(73) Assignee: Matsushita Electric Industrial Co., Ltd., Kadoma-shi (JP)

(21) Appl. No.: 11/069,672

(22) Filed: Mar. 1, 2005

(30) Foreign Application Priority Data
Mar. 2, 2004 (JP) 2004-057983

(51) Int. Cl. H01L 21/3205; H01L 21/4763; H01L 31/062

(52) U.S. Cl. 438/587

(57) ABSTRACT

A first impurity region 2 of a reverse conductivity type configuring a photoelectric conversion element and a buried channel region 3 of a reverse conductivity type configuring an element for transferring signal charges are formed in a principal surface portion of a semiconductor substrate 1 of one conductivity type, and a first insulating film 4 is formed on the semiconductor substrate. Then, a readout electrode 5 is formed in an area including a region on the buried channel region, and a second insulating film 6 for covering the readout electrode is formed. After that, a side wall forming film 7a is formed and a selective etching is carried out based on an etching selectivity ratio, thereby forming side walls 7 on side faces of the readout electrode with the second insulating film interposed therebetween. Then, ion implantation using the readout electrode and the side walls as masks is carried out to form a second impurity region 8 of one conductivity type in a self-alignment manner, followed by removal of the side walls. It is possible to obtain a reduced dark current, a stabilized readout voltage, etc., without decreasing the sensitivity, and to retain a sufficient thickness of the second insulating film.

### BACKGROUND OF THE INVENTION

1. Field of the Invention

The present invention relates to a method for manufacturing a solid-state imaging device having a reduced dark current and a stabilized readout voltage.

2. Description of the Related Art

Solid-state imaging devices having a buried-type photodiode structure as described in JP 57(1982)-062557 A are known generally. Also, in an attempt to reduce smear, a structure as described in JP 8(1996)-130299 A is applied generally to solid-state imaging devices.

Hereinafter, a typical conventional method for manufacturing a solid-state imaging device will be described. FIG. 3 is a cross-sectional view illustrating main portions of a conventional solid-state imaging device. FIG. 4 is a cross sectional view of the solid-state imaging device taken in a direction traversing a photoelectric element separation portion (element separation direction).

In FIGS. 3 and 4, reference numeral 21 denotes a P-type semiconductor substrate, in a principal surface region of which N-type impurity regions 22 configuring photoelectric conversion elements, buried channels 23 of vertical CCDs, P⁺-type impurity regions 27, and element separation regions 30 are formed. An insulating film 24 is formed on a surface of the P-type semiconductor substrate 21, and readout electrodes 25 are formed on the insulating film 24 so as to overlap the corresponding buried channels 23. Each of the readout electrodes 25 is covered with an insulating film 26 and a protective film 28. Further, a light shielding film 29 is formed on the protective film 28 such that an opening is provided only above each of the N-type impurity regions 22.

In light receiving portions of the conventional solid-state imaging device, surfaces of the N-type impurity regions 22 are covered with the P⁺-type impurity regions 27 so that a dark current is reduced. Each of the P⁺-type impurity regions 27 is formed by carrying out ion implantation mainly with boron so that it is self-aligned with respect to the readout electrodes 25 and performing a heat treatment.

According to the conventional manufacturing method as mentioned above, in order to reduce a dark current, it is necessary to optimize an impurity concentration and a diffusion length of each of the P⁺-type impurity regions 27. In other words, it is necessary to prevent ends of a depletion layer from contacting with an interface between the semiconductor substrate 21 and the insulating film 24.

In the above-mentioned conventional configuration, the P⁺-type impurity region 27 and the readout electrode 25 on surfaces of the P-type semiconductor substrate 21 overlap each other. Thus, to read out signal charges stably, a distance L1 between the N-type impurity region 22 and the buried channel 23 is required to be long. On the other hand, in order to reduce smear, it is necessary that the light shielding film 29 extends also above a part of the N-type impurity region 22 configuring a photoelectric conversion element so as to cover the readout electrode 25 completely. Accordingly, a size S1 of the opening of the photoelectric conversion element is reduced and the sensitivity is decreased.

Further, to ensure the size S1 of the opening while keeping an adequate distance L2 between the P⁺-type impurity region 27 and the buried channel 23 of a vertical CCD, the P⁺-type impurity region 27 may be formed using a mask of a resist pattern. However, this makes it difficult to provide a uniform distance between the readout electrode 25 and the P⁺-type impurity region 27, resulting in a variation in readout voltage. Also, with further miniaturization, the shape of the opening also varies due to an influence of a step formed by the readout electrode 25, which causes a variation not only in readout voltage but also in sensitivity.

Moreover, due to a steep concentration gradient of the P⁺-type impurity region 27 from a photoelectric element portion to a separation portion in a vertical separation direction, an electric field is likely to be concentrated. Therefore, the smear properties are degraded further.

JP 5(1993)-102457 A discloses a method for solving such problem. The method disclosed in JP 5(1993)-102457 A is such that a side wall is formed on a side face of the readout electrode, and an ion implantation is carried out using the readout electrode and the side wall as a mask to form the P⁺-type impurity region 27. However since the method employs a resist pattern for forming the sidewall, it is difficult to avoid a variation in the sidewall thickness due to a variation in a positioning of the resist pattern similarly to the above-mentioned method in which the P⁺-type impurity region 27 is formed using a resist pattern. Thus the method of JP 5(1993)-102457 A cannot solve the problem.

On the other hand, according to a miniaturization and a lowered operating voltage of an semiconductor element, a thickness of the insulating film 26 on the readout electrodes 25 tends to be made smaller. Above the readout electrodes 25, usually a transfer electrode is disposed with the insulating film 26 interposed therebetween. In a case of the insulating film 26 having smaller thickness, when a thickness of the insulating film 26 is reduced during etching process form forming the side wall, insulation between the readout electrodes 25 and the upper layer electrode becomes insufficient.

### SUMMARY OF THE INVENTION

An object of the present invention is to provide a method for manufacturing a solid-state imaging device that allows a dark current to be reduced, a readout voltage to be stabilized, and a voltage to be lowered without decreasing the sensitivity, and further that allows a sufficient thickness of the insulating film on the readout electrode to be retained, so as to keep a sufficient insulation between the readout electrode and the upper layer electrode.

In order to achieve the above-mentioned object, a method for manufacturing a solid-state imaging device of the present invention includes: forming selectively a first impurity region of a reverse conductivity type configuring a photoelectric conversion element in a principal surface portion of a semiconductor substrate of one conductivity type; forming a buried channel region of a reverse conductivity type configuring a transfer element for transferring signal charges from the photoelectric conversion element in the principal surface portion of the semiconductor substrate; forming a first insulating film on the semiconductor substrate; forming a readout electrode for reading out and transferring the signal charges from the photoelectric conversion element in an area including a region on the buried channel region on the first insulating film; forming a second insulating film for covering the readout electrode; forming a side wall forming film on the semiconductor substrate including a region on the second insulating film; carrying out an etching such that an etching rate for the side wall forming film is higher than that for the second insulating film, thereby removing the side wall forming film selectively to form side walls made of the side wall forming film on side faces of the readout electrode with the second insulating film interposed therebetween; carrying out ion implantation using the readout electrode and the side walls as masks to form a second impurity region of one conductivity type on a surface of the photoelectric conversion element in a self-alignment manner; and removing the side walls.

### BRIEF DESCRIPTION OF THE DRAWINGS

FIGS. 1A to 1D are cross-sectional views illustrating process steps of a method for manufacturing a solid-state imaging device according to one embodiment of the present invention.

FIG. 2 is a cross-sectional view of the solid-state imaging device manufactured through the process steps, taken in an element separation direction.

FIG. 3 is a cross-sectional view illustrating main portions of a solid-state imaging device manufactured by a conventional manufacturing method.

FIG. 4 is a cross-sectional view of the solid-state imaging device taken in an element separation direction.

### DETAILED DESCRIPTION OF THE INVENTION

According to a method for manufacturing a solid-state imaging device of the present invention, a second impurity region is formed in a self-alignment manner using side walls formed on side faces of a readout electrode as masks, whereby the second impurity region can be located accurately. The reason for this is that a variation in the size of the side walls is smaller than a variation in the size of a resist pattern. Consequently, the overlap of the readout electrode with the second impurity region is reduced as much as possible. Further, it is possible to reduce a projecting length of the readout electrode with respect to a buried channel region for transferring signal charges, thereby allowing an opening to be enlarged and improving the sensitivity. Moreover, due to a shielding effect of the side walls, the concentration gradient of the second impurity region from a photoelectric element portion to a separation portion in a vertical separation direction is allowed to be gentle and thus an electric field is not concentrated, resulting in improvement in the smear properties. Moreover, since the side wall is formed by carrying out an selective etching based on a etching selectivity ratio of the side wall forming film with respect to for the second insulating film, a thickness of the second insulating film is not reduced substantially. Therefore a sufficient thickness of the second insulating film can be retained, so as to keep a sufficient insulation between the readout electrode and the upper layer electrode.

In the method for manufacturing a solid-state imaging device of the present invention, in forming the side walls, an etching selectivity ratio of the side wall forming film with respect to the second insulating film preferably is not less than 30. More preferably, an etching selectivity ratio of the side wall forming film with respect to the first insulating film is more than 30.

The second insulating film may be made of a silicon oxide film, and the side wall forming film may be made of silicon. Alternatively, the second insulating film may be made of a silicon oxide film, and the side wall forming film may be made of amorphous silicon. Alternatively, the second insulating film may be made of a silicon oxide film, and the side wall forming film may be made of a silicon nitride film.

Preferably, the ion implantation for forming the second impurity region of one conductivity type is carried out from above the readout electrode in a direction tilted toward a readout side with respect to a direction perpendicular to the semiconductor substrate, so that shadows are formed by the readout electrode and the side walls.

The side walls may be removed by wet etching. A film thickness of the side wall forming film preferably is 50% to 300% of a thickness of the readout electrode. The readout electrode may be a metal electrode.

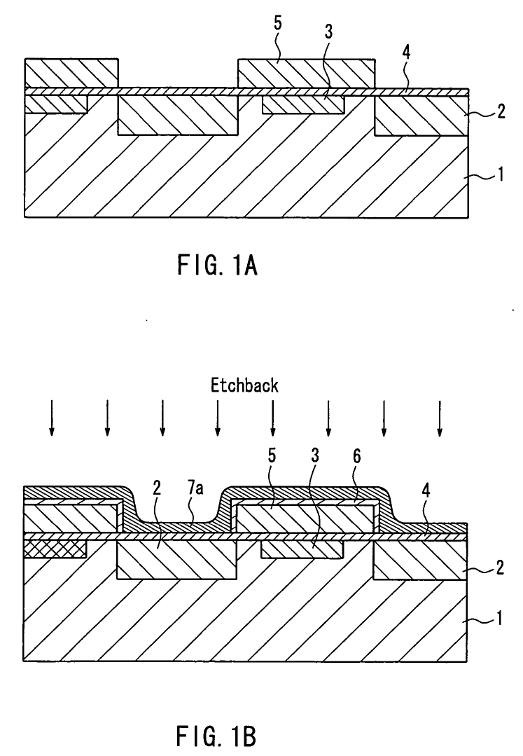

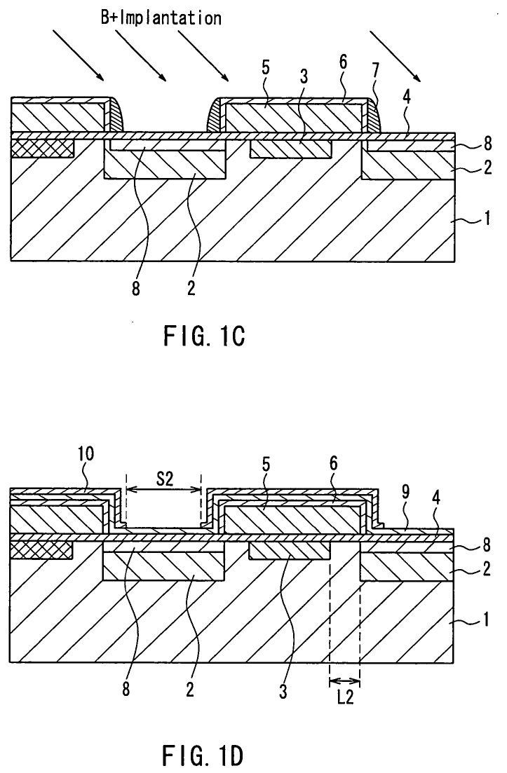

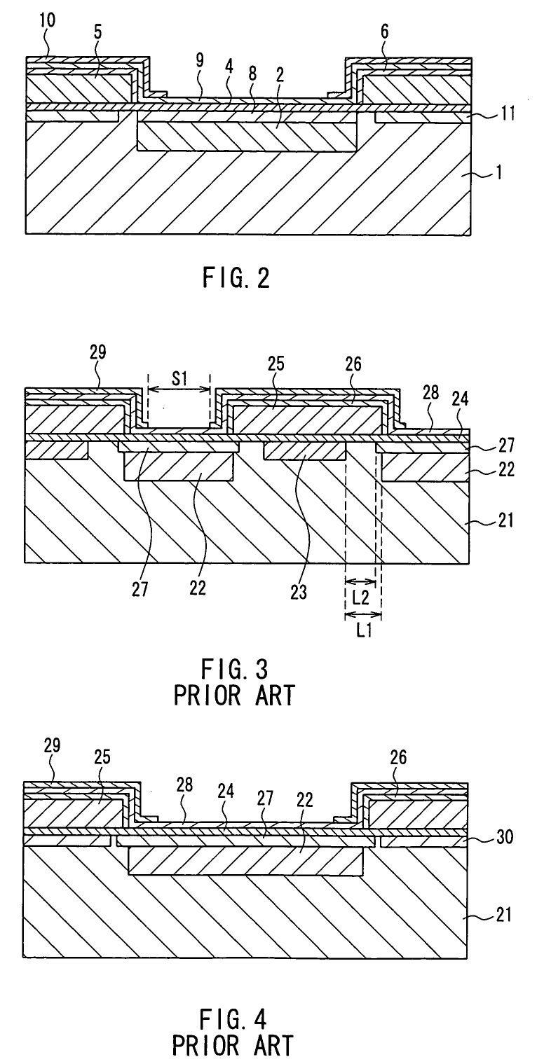

Hereinafter, a method for manufacturing a solid-state imaging device according to one embodiment of the present invention will be described with reference to the drawings. FIGS. 1A to 1C are cross-sectional views illustrating process steps of the manufacturing method. FIG. 2 is a cross-sectional view of a solid-state imaging device manufactured by the manufacturing method, taken in an element separation direction.

Initially, as shown in FIG. 1A, N-type impurity regions 2 configuring photoelectric conversion elements and N-type buried channel regions 3 are formed selectively in a principal surface region of a P-type silicon substrate 1. Then, readout electrodes 5 are formed on a surface of the silicon substrate 1 with a first insulating film 4 interposed therebetween. A material of the readout electrodes 5 may be polysilicon. The first insulating film 4 is formed of, for example, a so-called ONO (oxide-nitride-oxide) gate insulating film, which includes a thermally oxidized SiO₂ film/a silicon nitride film obtained by low-pressure CVD (Chemical Vapor Deposition)/a silicon nitride oxide film, in order from a substrate side. Further, as shown in FIG. 2, element separation regions 11 are formed.

Then, as shown in FIG. 1B, a second insulating film 6 for covering each of the readout electrodes 5 is formed. The second insulating film 6 may be composed of a silicon oxide film obtained by thermal oxidation of the readout electrodes 5. The thickness of the second insulating film 6 may be about 80 nm. Next, an amorphous silicon film (side wall forming film) 7a is formed on an entire face of the silicon substrate 1. The thickness of the amorphous silicon film 7a may be in a range of 100 nm to 300 nm.

Then the amorphous silicon film 7a is subjected to selective dry etching (etch back). An etching condition is set so that an etching rate for the side wall forming film is higher than that for the second insulating film 6, thereby forming side walls 7 on side faces of each of the readout electrodes 5 as shown in FIG. 1C.

After that, ion implantation is carried out in a direction tilted toward a readout side (left side in the FIG. 1C) with respect to a direction perpendicular to the silicon substrate 1 as shown by arrows in the figure, using the readout electrodes 5 and the side walls 7 as masks, thereby forming P⁺-type impurity regions 8 on surfaces of the corresponding N-type impurity regions 2 in a self-alignment manner. In general, the ion implantation carried out from an oblique direction as mentioned above is adopted because it is easy to control a depth of implantation at an appropriate position on the surfaces of the N-type impurity regions 2.

As the ion is implanted, the readout electrode 5 and the P⁺-type impurity region 8 are apart from each other on the readout side in FIG. 1C. However, at the time when the manufacturing process is completed, impurities are diffused such that the P⁺-type impurity region 8 covers an entire surface of the N-type impurity region 2 as shown in FIG. 1D due to a history of a heat treatment during the process. In order to obtain such a structure surely, the angle of gradient at which ions are implanted is adjusted in a range of not less than 1 degree to not more than 20 degrees. In a process step shown in FIG. 1D, after removing the side walls 7 by etching, a protective film 9 is formed and then a light-shielding film 10 is formed so that an opening is provided.

During the above-mentioned manufacturing process, in forming the side walls 7, a high etching selectivity ratio of the amorphous silicon film with respect to the first insulating film 4 and the second insulating film 6 is utilized, which thus preferably is not less than 30.

Since the side walls 7 are used as a mask material (stopper) when the P⁺-type impurity region 8 is formed, they preferably are made of amorphous silicon rather than polycrystalline silicon. A variation in the size of the side walls is improved to 3% as compared with 10%, the variation caused when a resist or the like is used. Further, in order to satisfy both the readout properties and the white flaw properties, a finished film thickness of the side wall 7 preferably falls within a range of 50% to 300% of the thickness of the readout electrode 5. The film thickness of the side wall 7 as used herein is the thickness of a film on a side face of the readout electrode 5 and thus corresponds to the width in a plane direction of the silicon substrate 1. In order to make the finished thickness of the side wall 7 fall within the range of 50% to 300% of the thickness of the readout electrode 5, the thickness of an amorphous silicon formed film preferably is 50% to 300% of the thickness of the readout electrode 5.

In the step of removing the side walls 7, wet etching is used preferably so as to avoid damaging the P⁺-type impurity regions 8 due to plasma or the like. Further, the side walls 7 are not necessarily removed completely, but they preferably are subjected to etching in a range in which no influence is exerted on the light receiving efficiency, so as to cause less damage onto the P⁺-type impurity regions 8.

According to the manufacturing method including the above-mentioned process steps, a variation in the size of the side walls is smaller than a variation in the size of resist masks or the like. Thus, even when a length of the P⁺-type impurity region 8 lying under the readout electrode 5 is reduced as much as possible, a positional relationship between the readout electrode 5 and the P⁺-type impurity region 8 adjacent to each other can be secured. It reduces a degree of modulation in the potential of the readout electrode 5 due to an influence of the P⁺-type impurity region 8, thereby obtaining a stabilized readout voltage and a lowered voltage.

Further, since the P⁺-type impurity region 8 can be located accurately, a distance L2 between the N-type buried channel region 3 of a vertical CCD as an effective gate length of the readout electrode 5 and the P⁺-type impurity region 8 can be reduced, thereby allowing an opening of each photoelectric conversion element to be enlarged. Further, due to a gentle concentration gradient of the P⁺-type impurity region 8 from a photoelectric element portion to a separation portion in a vertical separation direction, an electric field is not concentrated and thus favorable smear properties can be obtained.

Further, in forming the side wall 7, it is preferable that an etching condition is set so that an etching selectivity ratio of the amorphous silicon film 7a with respect to the second insulating film 6 is not less than 30. Thereby a reduction of a thickness of the second insulating film 6 during the etching is suppressed to be substantially zero. Therefore a sufficient thickness of the second insulating film can be retained, so as to keep a sufficient insulation between the readout electrode and the upper layer electrode such as a transfer electrode.

For example, in case in which the maximum rated voltage between the readout electrode 5 and the upper layer electrode is 25V, a tolerable minimum thickness of the second insulating film 6 is 50 nm. Therefore, if the original thickness of the second insulating film 6 is 80 nm as mentioned above, a reduction of a film thickness due to the etching for forming the side wall 7 should be limited to 30 nm or less. In such case, if the etching selectivity ratio of the amorphous silicon film 7a with respect to the second insulating film 6 is below 10, in a condition that a thickness of the amorphous silicon film 7a is 250 nm and a over etching of 50% is carried out, a reduction of film thickness becomes about 38 nm, which is below the tolerable minimum thickness. On the other hand, in case that the etching selectivity ratio of the amorphous silicon film 7a with respect to the second insulating film 6 is not less than 30, a reduction of film thickness becomes about 10 nm, thereby keeping the insulation by the second insulating film 6. It should be noted that 20% of the etching selectivity ratio may not be sufficient, if taking into consideration the concentration of electric field, since the second insulating film 6 is formed by thermal oxidation of the polysilicon.

In the above-mentioned example, the N-type impurity region 2 configuring a photoelectric conversion element and the readout electrode 5 do not overlap each other. However, the present embodiment may be applied to a solid-state imaging device having a structure in which the N-type impurity region 2 and the readout electrode 5 overlap each other or in which they are apart from each other, thereby achieving the same effects.

Further, in the above-mentioned example, the readout electrode 5 also serves as a transfer electrode. However, the present embodiment may be applied to the case where a transfer electrode is provided in addition to the readout electrode 5, thereby achieving the same effects.

Furthermore, in the above-mentioned example, when the P⁺-type impurity region 8 is formed so as to cover the surface of the N-type impurity region 2, the angle of gradient at which ions are implanted is adjusted. However, the film thickness of the side walls 7 may be adjusted, thereby achieving the same effects.

1. A method for manufacturing a solid-state imaging device comprising:
forming selectively a first impurity region of a reverse conductivity type configuring a photoelectric conversion element in a principal surface portion of a semiconductor substrate of one conductivity type;
forming a buried channel region of a reverse conductivity type configuring a transfer element for transferring signal charges from the photoelectric conversion element in the principal surface portion of the semiconductor substrate;
forming a first insulating film on the semiconductor substrate;
forming a readout electrode for reading out and transferring the signal charges from the photoelectric conversion element in an area including a region on the buried channel region on the first insulating film;
forming a second insulating film for covering the readout electrode;
forming a side wall forming film on the semiconductor substrate including a region on the second insulating film;
carrying out an etching such that an etching rate for the side wall forming film is higher than that for the second insulating film, thereby removing the side wall forming film selectively to form side walls made of the side wall forming film on side faces of the readout electrode with the second insulating film interposed therebetween;
carrying out ion implantation using the readout electrode and the side walls as masks to form a second impurity region of one conductivity type on a surface of the photoelectric conversion element in a self-alignment manner; and
removing the side walls.

2. The method for manufacturing a solid-state imaging device according to claim 1, wherein in forming the side walls, an etching selectivity ratio of the side wall forming film with respect to the second insulating film is not less than 30.

3. The method for manufacturing a solid-state imaging device according to claim 2, wherein an etching selectivity ratio of the side wall forming film with respect to the first insulating film is more than 30.

4. The method for manufacturing a solid-state imaging device according to claim 1, wherein the second insulating film is made of a silicon oxide film, and the side wall forming film is made of silicon.

5. The method for manufacturing a solid-state imaging device according to claim 1, wherein the second insulating film is made of a silicon oxide film, and the side wall forming film is made of amorphous silicon.

6. The method for manufacturing a solid-state imaging device according to claim 1, wherein the second insulating film is made of a silicon oxide film, and the side wall forming film is made of a silicon nitride film.

7. The method for manufacturing a solid-state imaging device according to claim 1, wherein the ion implantation for forming the second impurity region of one conductivity type is carried out from above the readout electrode in a direction tilted toward a readout side with respect to a direction perpendicular to the semiconductor substrate, so that shadows are formed by the readout electrode and the side walls.

8. The method for manufacturing a solid-state imaging device according to claim 1, wherein the side walls are removed by wet etching.

9. The method for manufacturing a solid-state imaging device according to claim 5, wherein a film thickness of the side wall forming film is 50% to 300% of a thickness of the readout electrode.

10. The method for manufacturing a solid-state imaging device according to claim 6, wherein the readout electrode is a metal electrode.
